(19) United States
(12) Patent Application Publication
(10) Pub. No.: US 2004/0035364 A1
(43) Pub. Date: Feb. 26, 2004

(54) Plasma processing apparatus and method for asssembling the plasma processing apparatus

(76) Inventors: Riki Tomoyoshi, Yamanashi-Ken (JP); Katsuyuki Koizumi, Yamanashi-Ken (JP)

Correspondence Address: SMITH, GAMBRELL & RUSSELL, LLP, 1850 M STREET, N.W., SUITE 800, WASHINGTON, DC, 20036, US

(21) Appl. No.: 10/416,568

(22) PCT Filed: Nov. 13, 2001
(86) PCT No.: PCT/JP01/09923

(30) Foreign Application Priority Data
Nov. 13, 2000 (JP) 2000345008

(51) Int. Cl. H01L 21/306; C23C 16/00

(52) U.S. Cl. 118/723 E; 156/345.1

(57) ABSTRACT

The plasma processing apparatus according to the present invention comprises a lower electrode 12 for supporting a wafer W in a chamber 11, shield member 19 for shielding an inside circumferential surface of the chamber 11 from a plasma for processing the wafer W, and a baffle plate 18 disposed in a gap between the shield member 19 and the lower electrode 12, and scattering and exhausting a gas in the chamber 11, a resin plate 20 being removably mounted on an inside circumferential surface of the shield member 19, and a circumferential compression stress being generated in the resin plate 20.

### BACKGROUND OF THE INVENTION

1. Field of the Invention

The present invention relates to a plasma processing apparatus and a method for fabricating the plasma processing apparatus, more specifically a plasma processing apparatus having the inside circumferential surface of a chamber improved in maintenance and a method for fabricating the plasma processing apparatus.

2. Related Background Art

A plasma processing apparatus comprises, an exemplified in FIG. 6, an air-tight structure processing vessel 1 (hereinafter called “a chamber”), a lower electrode 2 which functions also as a support and disposed on the bottom surface 1A of the chamber 1, and an upper electrode 3 disposed above the lower electrode 2 in parallel with the lower electrode 2. A plasma gas for etching, etc. is fed from the upper electrode 3 into the chamber 1 as indicated by the arrow A in FIG. 6. A high-frequency power source 4 for generating plasma is connected to the lower electrode 2 via a regulator 4A, and a high-frequency power source 5 for generating plasma is connected to the upper electrode 3 via a regulator 5A. High-frequency powers are applied respectively to the upper and the lower electrodes 2, 3 while a gas for plasma processing is being fed from the upper electrode 3 to thereby generate required plasma between the upper and the lower electrodes 2, 3, and the used gas is discharged through an exhaust port 1B as indicated by the arrow B.

A cylindrical support member 6A which is passed through a central hole formed in the bottom surface 1A of the chamber 1 is connected to the lower electrode 2 and interconnected, below the bottom surface 1A, to a drive mechanism 6B comprising a ball screw, etc. A bellows 7 is disposed between the outer circumferential surface of the upper end of the support member 6A and the bottom surface 1A. Thus, the lower electrode 2 is moved up and down in the chamber 1 by the drive mechanism so as to define a prescribed gap with respect to the upper electrode 3 when plasma processing is carried out.

A ring-shaped baffle plate 8 is mounted on the lower electrode 2 near the upper end thereof so as to discharge used gas to the exhaust port 1B from a plasma processing section 1C in the chamber 1 through the baffle plate 8. A shielded member 9 is removably mounted on the inside wall surface of the chamber 1, and protects the inside wall surface of the chamber 1. The shield member 9 protects the chamber 1 from ion attacks, prohibits the deposition of plasma by-products on the inside wall surface of the chamber 1 to thereby increase the effect of cleaning the chamber 1. The shield member 9 basically is formed of a material of the same quality as the chamber 1 and has the surface treated with the same surface-treatment as the chamber 1. For example, when the chamber 1 is made of aluminium having the surface anodized (formed in anodized aluminium film), the shield member 9 as well is formed of aluminium having the surface anodized (formed in anodized aluminium having the surface anodized (formed in anodized aluminium film).

However, when the shield member 9 has a part of the surface scraped off by plasma and partially loses the surface-treated film, in consideration of a risk that the loss of the surface treated film may affect the plasma processing, the shield member 9 is judged to have worn out as of the time even the loss of the surface is limited to a portion, and the shield member 9 must be replaced, which is a problem. Furthermore, the shield member 9 itself costs much to form, which makes the replacement cost higher, which is also a problem.

### SUMMARY OF THE INVENTION

The present invention was made to solve the above-described problems, and an object of the present invention is to provide a plasma processing apparatus which can prevent the inside wall surface of the chamber or the shield member from being damaged by plasma o that the shield member can be repeatedly used to consequently contribute to reduction of plasma processing costs, and which can prevent the deposition of plasma by-products on the inside wall surface of the processing vessel to thereby increase the cleaning effect, and a method for assembling the plasma processing apparatus.

The plasma processing apparatus according to the present invention, for generating a plasma in a processing vessel and plasma-processing an object-to-be-processed disposed in the processing vessel, wherein a resin plate is removably mounted on an inside circumferential surface of the processing vessel, which is to contact with the plasma, and a circumferential compression stress is generated in the resin plate.

The plasma processing apparatus according to the present invention comprises a support for supporting an object-to-be-processed in a processing vessel, a shield member for shielding an inside circumferential surface of the processing vessel from a plasma for processing the object-to-be-processed mounted on the support, and a baffle plate disposed in a gap between the shield member and the support, for scattering and exhausting a gas in the processing vessel, wherein a resin plate is removably mounted on an inside circumferential surface of the shield member, and a circumferential compression stress is generated in the resin plate.

In the plasma processing apparatus according to the present invention, the resin plate is mounted on the shield member covering at least a portion of the shield member located in a plasma region defined by the baffle plate.

In the plasma processing apparatus according to the present invention, the resin plate is formed in a strip-shape or a cylindrical shape.

In the plasma processing apparatus according to the present invention, the strip-shaped resin plate formed into a cylindrical shape, or the cylindrical resin plate has an outer circumferential length longer than an circumferential length of the inside circumferential surface of the processing vessel, or an circumferential length of an inside circumferential surface of the shield member by 0.01-0.4% of the length.

In the plasma processing apparatus according to the present invention, the strip-shaped resin plate formed into a cylindrical shape, or the cylindrical resin plate has an outer circumferential length longer than an circumferential length of the inside circumferential surface of the processing vessel, or an circumferential length of an inside circumferential surface of the shield member by 0.1-0.2% of the length.

According to the plasma processing apparatus according to the present invention, the resin plate mounted on the inside circumferential surface of the plasma processing vessel or the shield member prevents the processing vessel of the shield member from being damaged by plasma, and prevent the generation of particles from the processing vessel or the shield member due to ion sputtering, whereby the processing vessel or the shield member can be repeatedly used.

The method for assembling a plasma processing apparatus according to the present invention, for generating a plasma in a processing vessel and plasma-processing an object-to-be-processed disposed in the processing vessel, comprises the steps of forming a strip-shaped resin plate into a cylindrical shape having an outer circumferential length longer than an inner circumferential length of the processing vessel by overlapping both end portions of the strip-shaped resin plate over each other; contacting the cylindrically formed resin plate to the inside surface of the processing vessel with a part of the cylindrically formed resin plate flexed inward; and causing the flexed resin plate to restore the cylindrical shape and generating a circumferential compression stress in the resin plate.

The method for assembling a plasma processing apparatus according to the present invention, for generating a plasma in a processing vessel and plasma-processing an object-to-be-processed disposed in the processing vessel, comprises the steps of contacting a cylindrical resin plate having an outer circumferential length longer than an inner circumferential length of the processing vessel to an inside surface of the processing vessel with a part of the cylindrical resin plate flexed inward; and causing the flexed resin plate to restore the cylindrical shape and generating a circumferential compression stress in the resin plate.

The method for assembling a plasma processing apparatus according to the present invention, comprising a support for supporting an object-to-be-processed in a processing vessel, a shield member for shielding an inside circumferential surface of the processing vessel from a plasma for processing the object-to-be-processed mounted on the support, and a resin plate removably mounted on an inside circumferential surface of the shield member, comprises the steps of forming a strip of the resin plate into a cylindrical shape having an outer circumferential length longer than an inner circumferential length of the shield member by overlapping both ends of the strip-shaped resin plate over each other; contacting the cylindrically formed resin plate to an inside surface of the shield member with a part of the cylindrically formed resin plate flexed inward; and causing the flexed resin plate to restore the cylindrical shape and generating a circumferential compression stress in the resin plate.

The method for assembling a plasma processing apparatus comprising a support for supporting an object-to-be-processed in a processing vessel, a shield member for shielding an inside circumferential surface of the processing vessel from a plasma for processing the object-to-be-processed mounted on the support, and a resin plate removably mounted on an inside circumferential surface of the shield member, comprises the steps of contacting the cylindrical resin plate having an outer circumferential length longer than an inner circumferential length of the shield member to an inside surface of the shield member with a part of the cylindrical resin plate flexed inward; and causing the flexed resin plate to restore the cylindrical shape and generating a circumferential compression stress in the resin plate.

According to the method for assembling the plasma processing apparatus according to the present invention, the resin plate protects the processing vessel or the shield member from being damaged by plasma and prevent the generation of particles from the processing vessel or the shield member due to ion sputtering, and the resin plate can be easily removably mounted on the processing vessel or the shield member, whereby the resin plat can be readily replaced at site.

### BRIEF DESCRIPTION OF THE DRAWINGS

FIG 1 is a diagrammatic sectional view of a major part of the plasma processing apparatus according to one embodiment of the present invention.

FIG. 2A is a developed view of a resin plate which is a strip-shaped resin plate used in the plasma processing apparatus shown in FIG. 1.

FIG. 2B is a plan view of the resin plate of FIG. 2A as viewed from above.

FIG. 2C is a perspective view of the circled resin plate of FIG. 2A.

FIG. 2D is a longitudinal sectional view of the resin plate of FIG. 2A with both ends overlapped over each other.

FIG. 3A is a longitudinal sectional view of a jig for measuring a length of the resin plate shown in FIG. 1.

FIG. 3B is a front view of one end of the jig.

FIG. 3C is a front view of the other end of the jig.

FIG. 3D is an enlarged view of said one end of the jig.

FIG. 4 is perspective views of the resin plate shown in FIGS. 2A-2D in the steps of being mounted on the shield member.

FIG. 5 is perspective views of a resin plate used in another embodiment of the present invention in the steps of being mounted on a shield member.

FIG. 6 is a diagrammatic sectional view of the conventional plasma processing apparatus, which shows a structure thereof.

### DESCRIPTION OF PREFERRED EMBODIMENTS

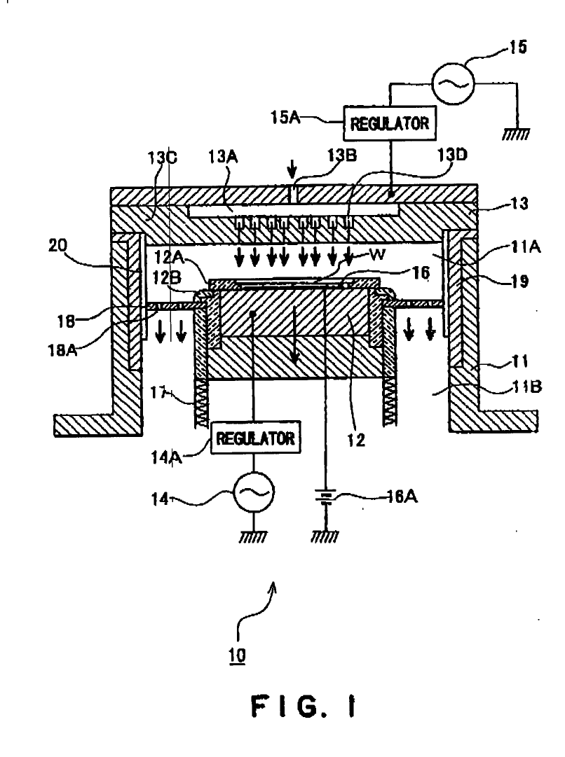

The present invention will be explained by means of embodiments shown in FIGS. 1 to 5.

A plasma processing apparatus according to the embodiments shown in FIGS. 1 to 5, comprises, as exemplified in FIG. 1, a chamber 11, a lower electrode 12 for mounting a wafer in the chamber 11, which is movable up and down, and an upper electrode 13 disposed above the lower electrode 12 in parallel with the lower electrode 12, and has a fundamental structure based on the conventional plasma processing apparatus. The lower electrode 12 is connected to a high-frequency power source 14 for generating a bias via a regulator 14A. The upper electrode 13 is connected to a high-frequency power source 15 via a regulator 15A. An electrostatic chuck 16 is disposed on the surface of the lower electrode 12. The electrostatic chuck 16 is supplied with a high voltage by a d.c. source 16A and electrostatically attracts a wafer W.

A focus ring 12A of ceramics, such as silicon carbide or others, is disposed on the outer peripheral edge of the lower electrode 12 to collect a plasma generated between the lower electrode 12 and the upper electrode 13 onto a wafer W by means of it. A protection cover 12B of, e.g., quartz is disposed on a portion of the lower electrode 12, which is to contact with plasma. The protection cover 12B protects the lower electrode 12 from plasma. The upper electrode 13 has, e.g., a cavity 13A. A processing gas is fed through a gas feed port 13B formed through the upper portion of the upper electrode 13 at the center thereof and fed into the chamber 11 through feed holes 13D formed in the lower portion 13C of the upper electrode 13. In FIG. 1, reference number 17 denotes a bellows.

An annular baffle plate 18 is disposed on an upper end part of the lower electrode 12, and a gas which has been used in the plasma processing is discharged, through holes 18A formed circumferentially in the baffle 18, from the plasma processing region 11A to the side of an exhaust region 11B. The baffle plate 18 is made of, e.g., aluminium having the surface anodized (formed in anodized aluminium film).

As shown in FIG. 1, a cylindrical shield member 19 having a flange on the upper end is mounted on an upper inside circumferential surface of the chamber 11. The shield member 19 is formed of, e.g., aluminium having the surface anodized (formed in anodized aluminium film) and covers the inside circumferential surface of the chamber 11. In the present embodiment, a resin plate 20 is further replaceably mounted on the inside circumferential surface of the shield member 19. The resin plate 20 is made of, e.g., heat-resistant resin. Although a material of the resin plate 20 is not essentially limited as long as the material is heat-resistant, but is preferably made of a polyimide resin, such as VESPEL (trade name of DuPont) or others, a polyimide amide resin, such as SELLASOL (trade name of CLARIANT) or others, or a tetra-ethylene fluoride resin, or others. A material of the shield member 19 is selected to be compatible with a material of, e.g., the chamber.

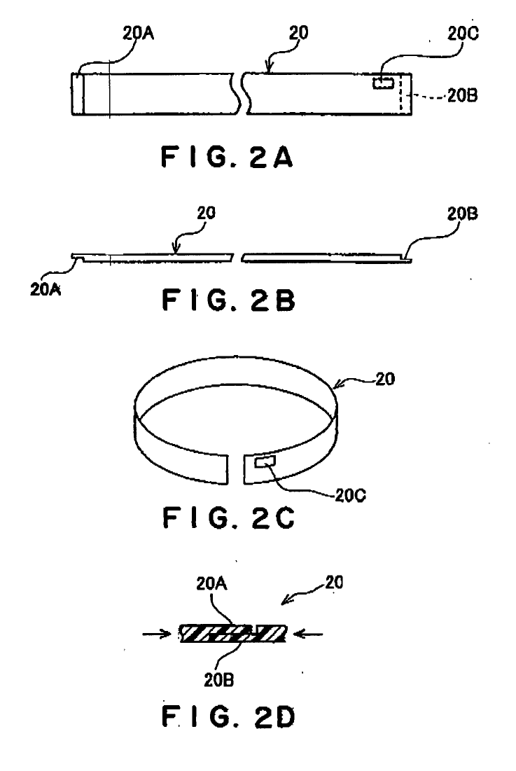

The resin plate 20 is formed in a strip as exemplified in FIGS. 2A-2D. The strip has both end portions reduced in thickness, and the both end portions are formed in overlapping portions 20A, 20B as shown in FIGS. 2A and 2B. When the resin plate 20 is mounted on the shield member 19, the resin plate 20 is circled as shown in FIG. 2C, and the overlapping portions 20A, 20B on both ends are overlapped over each other to form the resin plate into a cylindrical shape as shown in FIG. 2D. The strip-shaped resin plate 20 formed into the cylindrical shape has an outer circumferential length before mounted which is larger than an inner circumferential length of the shield member 19 by 0.01-0.4%, preferably by 0.1-0.2% of the inner circumferential length of the shield member 19. An outer circumferential length of the resin plate 20 formed in the cylindrical shape with the overlapping portions 20A, 20B overlapped over each other is thus set to be larger than an inner circumferential length of the shield member 19, whereby when the resin plate 20 is mounted on the shield member 19, one end surface of one of the overlapping portions 20A, 20B is in abutment on the steps of the other overlapping portion, and a circumferential compression stress as indicated by the arrows in FIG. 2D is generated in the resin plate 19 to press the resin plate 20 tightly against the shield member 19 to thereby prohibit the resin plate 20 from coming off the shield member 19. A lateral dimension of the resin plate 20 is so set that the resin plate 20 can cover the inside circumferential surface of the shield member 19 in a region upper of the baffle plate 18 during at least the plasma processing, whereby the shield member 19 is not exposed directly to th plasma. Preferably, a lateral dimension of the resin plate 20 is so set that the resin plate 20 can be extended lower of the baffle plate 18. A thickness of the resin plate 20 can be suitably set but preferably is set to be about 1.5-2.0 mm in terms of the fabrication. In FIGS. 2A and 2C, reference number 20C indicates a hole as a window for detecting the end of the process.

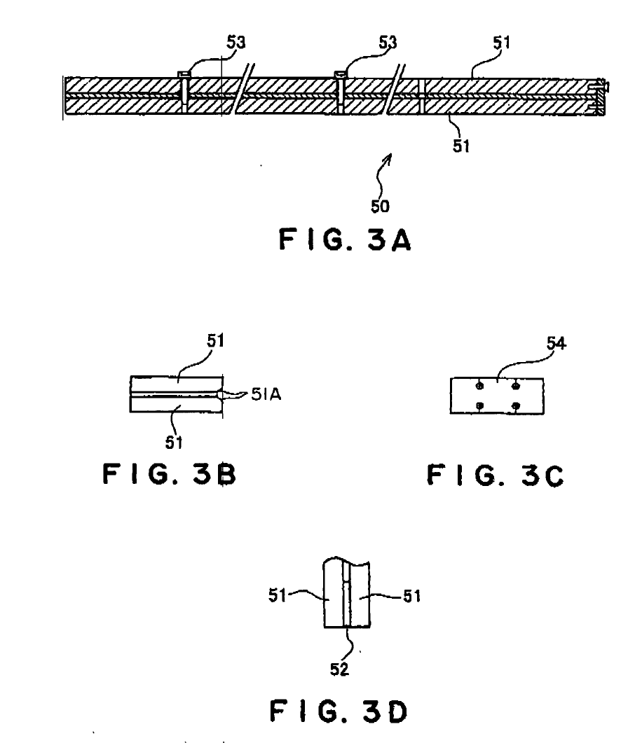

It is very important to set a longitudinal dimension of the strip-shaped resin plate 20 with high precision. The resin plate 20 of a too large length or a too small length is difficult to be mounted closely on the shield member 19. Then, in the present embodiment, the jig 50 shown in FIGS. 3A-3D is used to precisely set a length of the resin plate 20. The job 50 comprises a pair of plates formed of, e.g., aluminium in strips, a thickness setting member 52 clamped by he pair of plates 51, 51, a plurality of screw members 53 which fastening together both plates 51, 51 with the thickness setting member 52 held therebetween, and a locking plate 54 which blocks one ends of both plates 51, 51. Both plates 51, 51 have the inside surface of the respective upper ends formed in tapered surfaces 51A, 51A. The tapered surfaces 51A, 51A are guide surfaces for inserting the resin plate 20 into the jig 50. The jig 50 is placed in a thermostatic chamber (not shown) to be kept in a state in which the jig 50 can be always used at a prescribed temperature (e.g., 23° C.±3°) to precisely set a length of the resin plate 20. When dimensions of the resin plate 20 are set, the resin plate 20 is inserted between both plates 51, 51, and one end of the resin plate 20 is brought into abutment on the locking plate 54. The other end of the resin plate 20 is a little projected beyond the other end of the jig 50, and the projected portion of the resin plate 20 is cut off to thereby precisely set the resin plate 20 in a prescribed length. The jig 50 can be also used as a jig for delivery inspection.

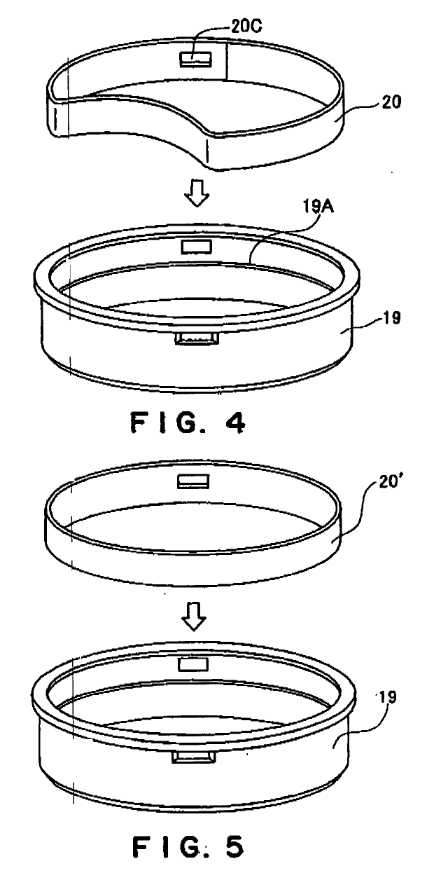

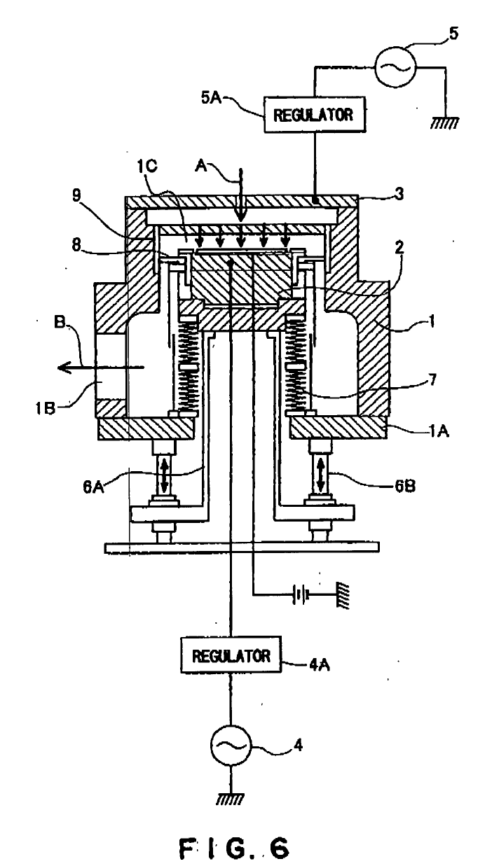

Then, a method for mounting the strip-shaped resin plate 20 on the shield member 19 will be explained by referring to FIG. 4. The overlapping portions 20A, 20B on both ends of the strip-shaped resin plate 20 are overlapped over each other to form the strip-shaped resin plate 20 into a cylindrical shape. A part of the cylindrical shape in this state is flexed inward as shown in FIG. 4 to be easily inserted into the shield member 19. Then, as indicated by the arrow, the cylindrical part of the resin plate 20 is overlapped over the inside circumferential surface of the shield member 19, and then the inwardly flexed part is flexed back toward the inside circumferential surface of the shield member 19 to restore the cylindrical state, and the resin plate 20 is tightly contacted to the inside circumferential surface of the shield member 19 over the entire circumference. The outer circumferential length of the resin plate 20 is larger than an inner circumferential length of the shield member 19 by 0.01-0.4%, preferably by 0.1-0.2% of the length of the shield member 19, whereby a compression stress is generated circumferentially in the cylindrical resin plate 20 to be tightly contacted to the inside circumferential surface of the shield member 19 while a reaction force is generated circumferentially in the cylindrical resin plate 20. Resultantly, the resin plate 20 expands its inner diameter to be tightly contacted to the inside circumferential surface of the shield member 19. The resin plate 20 in this state cannot easily come off. A step 19A formed on the inside circumferential surface of the shield member 19 abuts on the lower end of the resin plate 20.

The shield member 19 with the resin plate 20 mounted on is mounted on the inside circumferential surface of the chamber 11, and the plasma processing apparatus 10 comprising the chamber 11 having the inside circumferential surface of the chamber 11 in the plasma generating section covered with the resent plate 20 as shown in FIG. 1 is assembled. In making plasma processing on a wafer W by using the plasma processing apparatus 10, ions in the plasma attack the inside circumferential surface of the chamber 11 due to a potential difference between a plasma potential and a ground potential of the chamber 11. In the present embodiment, the resin plate 20 covering the shield member 19 mounted on the inside circumferential surface of the chamber 11 is sacrificed to protect the shield member 19 from being damaged. Furthermore, in the present embodiment, in which ions do not directly attack the shield member 19, as do in the conventional plasma processing apparatus, no particle is caused by the ion sputtering, which can improve yields of the plasma processing. When the resin plate 20 is worn by the plasma processing, the worn resin plate 20 is simply replaced so that the shield member 19 itself can be repeatedly used. Furthermore, the resin plate 20 can be easily removed from the shield member 19 so that the resin plate 20 can be readily replaced at site.

When by-products are generated in plasma, the by-products are deposited on the inside circumferential surface of the resin plate 20 without being deposited directly on the shield member 19. Accordingly, when the chamber 11 is cleaned, the resin plate 20 is simply replaced without performing the cleaning. The cleaning can be efficient.

As described above, according to the present embodiment, the resin plate 20 is replaceably mounted on the inside circumferential surface of the shield member 19, and besides a circumferential compression stress is generated in the resin plate 20, whereby plasma is prohibited from entering between the resin plate 20 and the shield member 19 to thereby damage the shield member 19. When the resin plate 20 is worn, the resin plate 20 is simply replaced by a new one so that the expensive shield member 19 can be repeatedly used as it is, which can contribute to the cost reduction of the plasma processing apparatus. The resin plate 20 can be readily replaced at site. By-products of plasma are deposited on the resin plate 20 without being deposited directly on the shield member 19, which allows the cleaning of the inside circumferential surface of the chamber 11 to be omitted, and the cleaning can be efficient. The resin plate 20 is light and does not take up space, and supplies of the resin plate 20 can be readily stored.

FIG. 5 shows a resin plate 20′ of another embodiment of the present invention in a state of the resin plate 20′ mounted on a shield member 19. The resin plate 20′ is initially formed in a cylindrical shape. A circumferential length of the resin plate 20′ is the same as a length of a strip-shaped resin plate 20 formed in the cylindrical shape. That is, an outer circumferential length of the cylindrical resin plate 20′ before mounted on the shield member 19 is set to be larger than an inner circumferential length of the shield member 19 by 0.01-0.4%, preferably by 0.1-0.2% of the inner circumferential length of the shield member 19.

When the cylindrical resin plate 20′ is mounted on the shield plate 19, as is shown in FIG. 4, the resin plate 20′ is mounted on the shield member 19 while a part of the cylindrical resin plate 10′ is being flexed inward. When the resin plate 20′ is mounted on the shield member 19, a circumferential compression stress is generated in the resin plate 20′ while a force to expand a diameter of the resin plate 20′ is exerted, whereby the resin plate 20′ is tightly contacted to the shield member 19. In the present embodiment as well, the same advantageous effects as produced by the above-described embodiment can be produced. In FIG. 5, a step 19A formed on the inside circumferential surface of the shield member 19 is abutted on the lower end of the resin plate 20′.

The present invention provides a plasma processing apparatus which can prevent the inside wall surface of the chamber, or the shield member from being damaged by plasma so that the processing vessel or the shield member can be repeatedly used to consequently contribute to reduction of plasma processing costs, and which can prevent the deposition of plasma by-products on the inside wall surface of the processing vessel or on the shield member to thereby improve the cleaning effect, and a method for assembling the plasma processing apparatus.

What is claimed is:

1. A plasma processing apparatus for generating a plasma in a processing vessel and plasma-processing an object-to-be-processed disposed in the processing vessel, wherein
a resin plate is removably mounted on an inside circumferential surface of the processing vessel, which is to contact with the plasma, and
a circumferential compression stress is generated in the resin plate.

2. A plasma processing apparatus comprising a support for supporting an object-to-be-processed in a processing vessel, a shield member for shielding an inside circumferential surface of the processing vessel from a plasma for processing the object-to-be-processed mounted on the support, and a baffle plate disposed in a gap between the shield member and the support, for scattering and exhausting a gas in the processing vessel, wherein
a resin plate is removably mounted on an inside circumferential surface of the shield member, and
a circumferential compression stress is generated in the resin plate.

3. The plasma processing apparatus according to claim 2, wherein
the resin plate is mounted on the shield member covering at least a portion of the shield member located in a plasma region defined by the baffle plate.

4. The plasma processing apparatus according to any one of claims 1 to 3, wherein
the resin plate is formed in a strip-shape or a cylindrical shape.

5. The plasma processing apparatus according to any one of claims 1 to 4, wherein
the strip-shaped resin plate formed into a cylindrical shape, or the cylindrical resin plate has an outer circumferential length longer than a circumferential length of the inside circumferential surface of the processing vessel, or an circumferential length of the inside circumferential surface of the shield member by 0.01-0.4% of the circumferential lengths of the processing vessel or the shield member.

6. The plasma processing apparatus according to any one of claims 1 to 4, wherein
the strip-shaped resin plate formed into a cylindrical shape, or the cylindrical resin plate has an outer circumferential length longer than a circumferential length of the inside circumferential surface of the processing vessel, or an circumferential length of the inside circumferential surface of the shield member by 0.1-0.2% of the circumferential lengths of the processing vessel or the shield member.

7. A method for assembling a plasma processing apparatus for generating a plasma in a processing vessel and plasma-processing an object-to-be-processed disposed in the processing vessel, comprising the steps of:
forming a strip-shaped resin plate into a cylindrical shape having an outer circumferential length longer than an inner circumferential length of the processing vessel by overlapping both end portions of the strip-shaped resin plate over each other;
contacting the cylindrically formed resin plate to the inside surface of the processing vessel with a part of the cylindrically formed resin plate flexed inward; and
causing the flexed resin plate to restore the cylindrical shape and generating a circumferential compression stress in the resin plate.

8. A method for assembling a plasma processing apparatus for generating a plasma in a processing vessel and plasma-processing an object-to-be-processed disposed in the processing vessel, comprising the steps of:
contacting a cylindrical resin plate having an outer circumferential length longer than an inner circumferential length of the processing vessel to an inside surface of the processing vessel with a part of the cylindrical resin plate flexed inward; and
causing the flexed resin plate to restore the cylindrical shape and generating a circumferential compression stress in the resin plate.

9. A method for assembling a plasma processing apparatus comprising a support for supporting an object-to-be-processed in a processing vessel, a shield member for shielding an inside circumferential surface of the processing vessel from a plasma for processing the object-to-be-processed mounted on the support, and a resin plate removably mounted on an inside circumferential surface of the shield member, the method comprising the steps of:
forming a strip of the resin plate into a cylindrical shape having an outer circumferential length longer than an inner circumferential length of the shield member by overlapping both ends of the strip-shaped resin plate over each other;
contacting the cylindrically formed resin plate to an inside surface of the shield member with a part of the cylindrically formed resin plate flexed inward; and
causing the flexed resin plate to restore the cylindrical shape and generating a circumferential compression stress in the resin plate.

10. A method for assembling a plasma processing apparatus comprising a support for supporting an object-to-be-processed in a processing vessel, a shield member for shielding an inside circumferential surface of the processing vessel from a plasma for processing the object-to-be-processed mounted on the support, and a resin plate removably mounted on an inside circumferential surface of the shield member, the method comprising the steps of:
contacting the cylindrical resin plate having an outer circumferential length longer than an inner circumferential length of the shield member to an inside surface of the shield member with a part of the cylindrical resin plate flexed inward; and
causing the flexed resin plate to restore the cylindrical shape and generating a circumferential compression stress in the resin plate.
